(19) United States
(12) Patent Application Publication
(10) Pub. No.: US 2014/0175233 A1
(43) Pub. Date: Jun. 26, 2014

(54) CABLE CLAMP

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: YU HAN, Shenzhen (CN); BO TIAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/772,327

(22) Filed: Feb. 21, 2013

(30) Foreign Application Priority Data
Dec. 26, 2012 (CN) 201210573964.6

(51) Int. Cl. H05K 7/02

(52) U.S. Cl. CPC H05K 7/02
USPC 248/74.1

(57) ABSTRACT

A cable clamp includes a clamp member for clamping cables, and a fastener. The clamp member defines a fixing hole. An annular first gear portion is formed on an inner sidewall bounding the fixing hole. The fastener extends through the fixing hole to engage in a motherboard, to mount the clamp member to the motherboard. An annular second gear portion extends from the fastener and movably meshes with the first gear portion.

### BACKGROUND

1. Technical Field

The present disclosure relates to a cable clamp.

2. Description of Related Art

Many cable clamps are often mounted to sidewalls of a computer enclosure to clamp cables arranged above a motherboard. However, these cable clamps are generally unmovable, and can only clamp cables extending in a fixed direction, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a cable clamp including a fastener, together with a motherboard.

FIG. 2 is an inverted, enlarged view of the fastener of FIG. 1.

FIG. 3 is an assembled, isometric view of FIG. 1.

FIG. 4 is a cross-sectional view of FIG. 3, taken along the line IV-IV.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

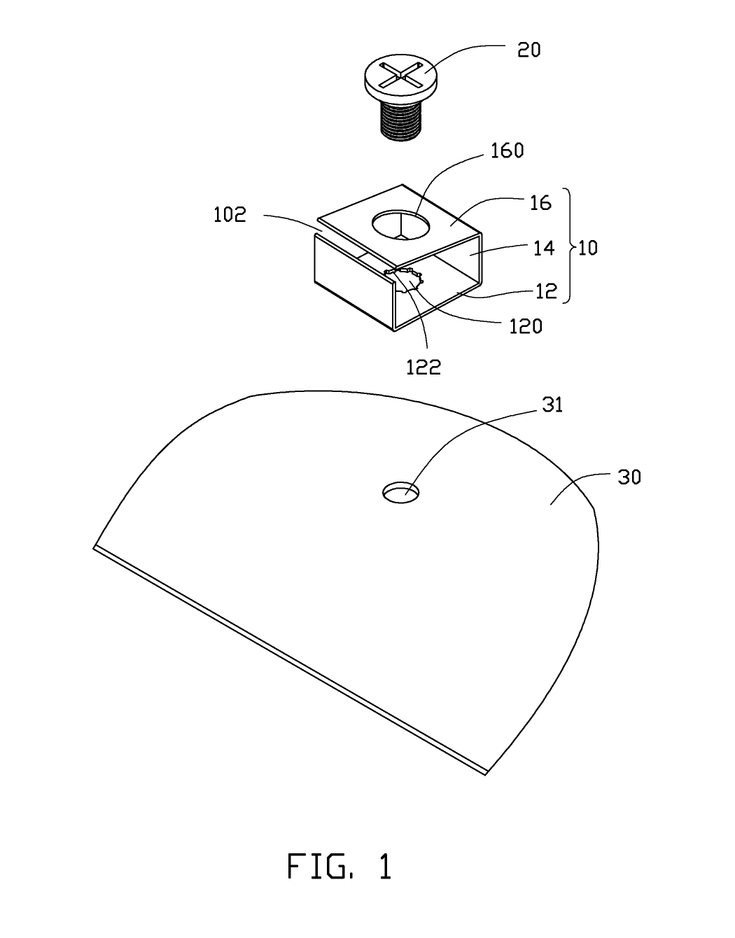

FIG. 1 shows an embodiment of a cable clamp to be mounted to a motherboard 30. The motherboard 30 defines an installing hole 31. The cable clamp includes a clamp member 10 and a fastener 20.

The clamp member 20 includes a bottom wall 12, two opposite sidewalls 14 extending substantially perpendicularly from opposite sides of the bottom wall 12, a covering piece 16 extending substantially perpendicularly from a top side of one of the sidewalls 14 toward the other sidewall 16. An opening 102 is defined between the covering piece 16 and the other sidewall 16. The bottom wall 12 defines a fixing hole 120 extending through top and bottom surfaces of the bottom wall 12. An annular first gear portion 122 protrudes from an inner sidewall bounding the fixing hole 120. The covering piece 16 defines a through hole 160 aligning with the fixing hole 120. A diameter of the through hole 160 is greater than a diameter of the fixing hole 120.

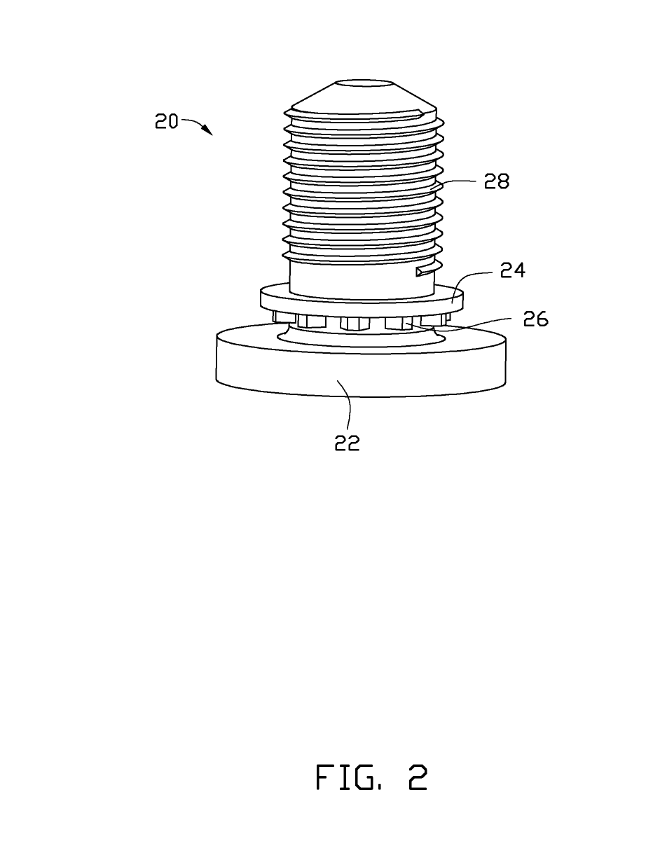

Referring to FIG. 2, the fastener 20 includes a head 22, a blocking potion 24, an annular second gear portion 26 connected between the head 22 and the blocking portion 24, and a threaded pole 28 extending from a side of the blocking portion 24 away from the head 22.

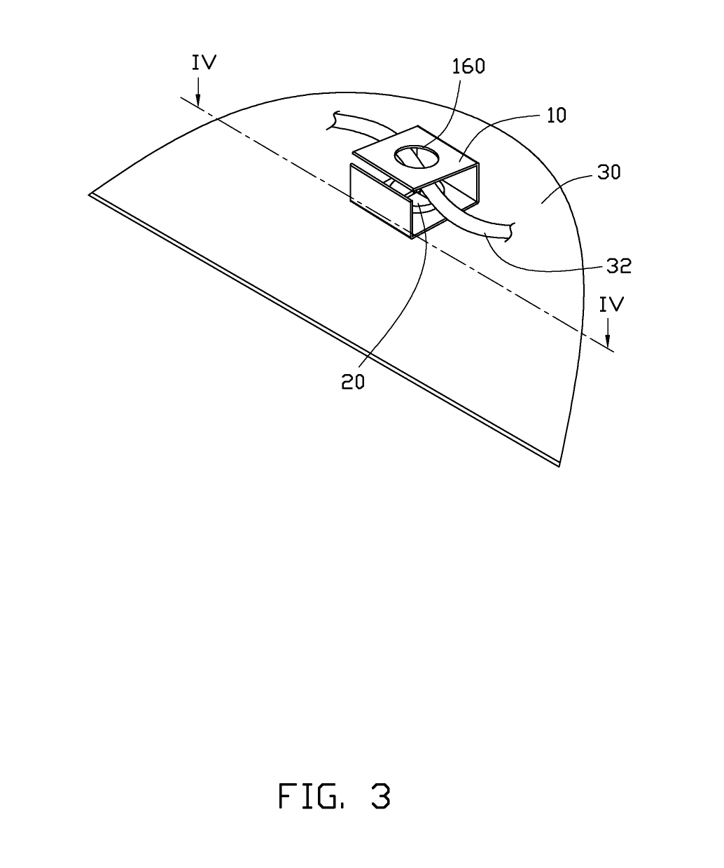

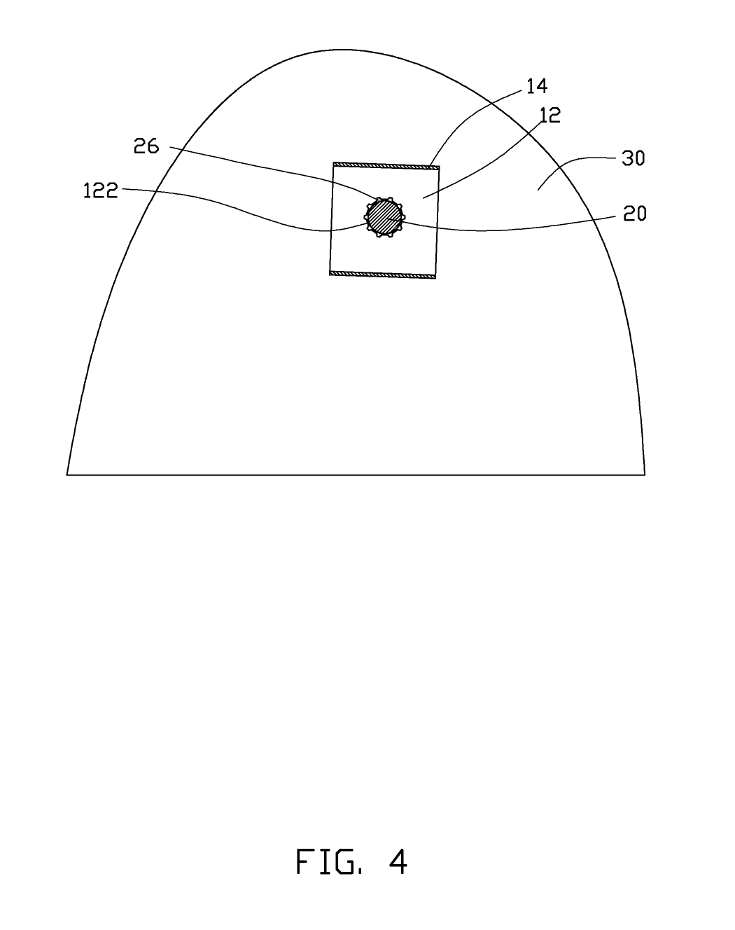

Referring to FIGS. 3 and 4, in assembly, the threaded pole 28 extends through the through hole 160, the fixing hole 120, and then engaged in the installing hole 31, until the blocking portion 24 contacts a top surface of the motherboard 30, and the second gear portion 26 movably meshes with the first gear portion 122, and the head 22 contacts the top surface of the bottom wall 12. Cables 32 above the motherboard 30 pass through the opening 102 to be clamped among the sidewalls 14, the covering piece 16, and the bottom wall 12. Because the second gear portion 26 meshes with the first gear portion 122, the clamp member 10 can be rotated to change the orientation of the opening 102 to accommodate cables passing through from different directions.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

1. A cable clamp, comprising:
a clamp member to clamp cables, the clamp member defining a fixing hole, and having an annular first gear portion protruding from an inner sidewall of the interior of the fixing hole; and
a fastener extending through the fixing hole to mount the clamp member to a motherboard, wherein an annular second gear portion is formed on the fastener and movably meshes with the first gear portion, and wherein the fastener comprises a head and a threaded pole, and the second gear portion is connected between the head and the threaded pole.

2. The cable clamp of claim 1, wherein the clamp member comprises a bottom wall, and two opposite sidewalls extending substantially perpendicularly from opposite sides of the bottom wall to clamp the cables, and the fixing hole is defined in the bottom wall.

3. The cable clamp of claim 2, wherein the clamp member further comprises a covering piece extending substantially perpendicularly from a top side of one of the sidewalls toward the other sidewall, the covering piece defines a through hole aligning with the fixing hole, and the through hole has a greater diameter than the fixing hole.

4. The cable clamp of claim 3, wherein an opening is defined between the covering piece and the other sidewall.

5. (canceled)

6. The cable clamp of claim 1, wherein the fastener further comprises a blocking portion to contact the motherboard, and the blocking portion is positioned between the second gear portion and the threaded pole.
